(19) United States
(12) Patent Application Publication
(10) Pub. No.: US 2009/0040727 A1
(43) Pub. Date: Feb. 12, 2009

(54) Circuit Carrier Structure with Improved Heat Dissipation

(75) Inventor: Michael Decker, Regensburg (DE)

Correspondence Address: LERNER GREENBERG STEMER LLP, P O BOX 2480, HOLLYWOOD, FL, 33022-2480, US

(73) Assignee: CONTINENTAL AUTOMOTIVE GMBH, Hannover (DE)

(21) Appl. No.: 12/187,737

(22) Filed: Aug. 7, 2008

(30) Foreign Application Priority Data
Aug. 7, 2007 (DE) 10 2007 037 297.5

(51) Int. Cl. H05K 7/20

(52) U.S. Cl. 361/705

(57) ABSTRACT

A circuit carrier structure has at least one electronic component and is formed using SMD technology. Underneath the at least one electronic component is arranged a continuous recess in a circuit carrier. A die made of a heat-conducting material is inserted with one end of a joining area into the recess and fixed in place with a layer of heat-conducting cement and connected to the component in a heat-conducting manner. Further the die has on its other side a linkage area, whose cross-sectional area is at least in part of larger dimensions than the recess in the circuit carrier and whose end is connected to a heat sink in a heat-conducting manner.

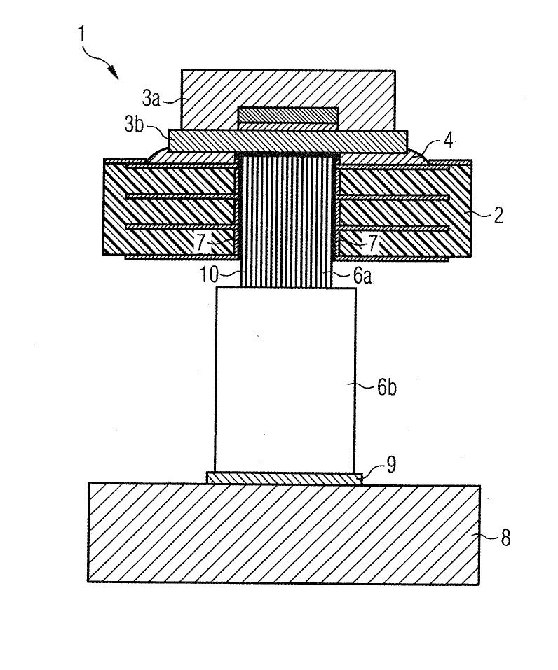

### CROSS-REFERENCE TO RELATED APPLICATION

This application claims the priority, under 35 U.S.C. § 119, of German application DE 10 2007 037 297.5, filed Aug. 7, 2007; the prior application is herewith incorporated by reference in its entirety.

### BACKGROUND OF THE INVENTION

### Field of the Invention

The invention relates to a circuit carrier structure having at least one electronic component based on SMD technology and a method for manufacturing such a circuit carrier structure, in particular for applications in the automotive industry.

In the development of printed circuit board technology, the constantly growing requirements of electrical packaging technology play a major role. The component density of electrical components on printed circuit boards is increasing all the time, as ever more complex circuits must be accommodated within ever smaller dimensions. Because of a high component density and as a result of the use of power components, which in some cases generate high dissipated energy in the form of heat, more exacting requirements in terms of improved heat management, that is the selective driving off of heat losses from the point of origin and its dissipation into the environment are posed.

Various concepts are known, by which the dissipation of heat generated by the power units in the case of circuit carrier structures is achieved.

One approach consists of coupling the dissipated energy generated by the electronic components into the printed circuit board, which can distribute and dissipate the heat through its copper layer material. The printed circuit board can here be mounted on a metallic carrier plate, which serves as a heat sink to dissipate heat. Similarly the SMD power components in particular can additionally contain a main body and a solderable lower part, which not only provides mechanical stabilization, but also serves as a cooling surface, and is known as a heat vane.

In the case of circuit carrier structures, the SMD components are generally mounted on the upper surface of the printed circuit board facing away from the heat sink. In order significantly to improve the heat dissipation from the SMD component through the circuit carrier vertically to the copper layer structure and to the heat sink, a known method is to equip the printed circuit board underneath the overlaid power components with galvanized feedthroughs, so-called thermal vias. Feedthroughs of this kind generally contain small-diameter (<1 mm) holes drilled through the printed circuit board. These can be filled with heat-conducting materials such as pastes, gels or cements. However because of the geometry of the feedthrough, only an inadequate level of heat dissipation from the component to the heat sink can be achieved, even in the case of a large number of feedthroughs underneath an individual power component.

Published, non-prosecuted German patent application DE 43 26 506 A1 discloses a conductive foil populated with SMD power components which is mounted on a carrier plate for mechanical stabilization and as a measure for improving the dissipation of heat generated by the power components. Below the power component a solderable peripheral layer is embodied on the conductive foil, which delimits a recess of large area. This recess is filled with a heat-conducting mass, preferably with a solder paste, so that heat transfer from the power component to the carrier plate over a large area is possible.

With the introduction of copper-inlay-technology, markedly improved heat dissipation compared to that achieved by using thermal vias became possible. Through the insertion of solid copper elements, known as copper inlays, into a printed circuit board, the heat arising from the dissipated energy from electrical components can be very effectively dissipated. In this way, the thermal resistance of the printed circuit board can be significantly reduced. Critical increases in temperature can be avoided, and the module operated and kept within the permissible temperature limits. By these measures it is possible to achieve a significant improvement in the reliability and service life of electronic modules. Such modules are also suitable for use in high frequency technology. A copper inlay can be inserted into the full thickness of the printed circuit board and its dimensions adapted to the thickness of the printed circuit board. Here the copper inlay serves on the one hand, with its entire upper face, as a soldering surface for the mounting of electrical components and on the other as a high-performance heat-conducting path through the printed circuit board. Depending on requirements, the copper inlay can then in turn be connected via its undersurface to the casing or to an additional heat sink, with known heat-conducting cements or heat-conducting foils. Linking the inlay to electrical components by soft solder has the disadvantage that this is mechanically unstable, and can readily become prone to fracturing. Fractures in turn mean that the heat conducting properties are markedly reduced. In addition this form of linkage offers no overvoltage protection and the dissipation of heat from components driven by electrical potential cannot take place by such measures.

A further known concept for the dissipation of heat from electrical components is so-called top cooling. In the case of components with curved connecting legs (gull wings), the possibility exists of establishing a heat vane from the circuit carrier in a groundbreaking manner. Here the thermal linkage is not realized by the circuit carrier, but directly on a heat sink. Depending on their type and manufacturer, components linked in this way to a heat sink on the side facing away from the circuit carrier are of different sizes and heights. If the lowest possible thermal resistance is to be realized, in the case of the top cooling concept the heat sink and component placement can be developed only in conjunction with each other and not independently.

The secure and effective dissipation of heat from electronic power components has a direct influence on their service life and thus the reliability of circuit carriers and the electronic devices created with them in their entirety. The development of new alternative concepts for high-performance heat conducting paths thus plays a major role in the development of new electronic modules and devices.

### SUMMARY OF THE INVENTION

It is accordingly an object of the invention to provide a circuit carrier structure with improved heat dissipation which overcomes the above-mentioned disadvantages of the prior art devices and methods of this general type, which enables the improved and secure dissipation of the heat generated by electronic components, and can thus prolong the service life of the components.

According to the invention a circuit carrier structure with at least one SMD electronic component is proposed, in which underneath the at least one SMD component is arranged a continuous recess in the circuit carrier. A die made of a heat-conducting material is introduced into the recess with one end of a joining area and fixed with a heat-conducting cement, and connected to the component in a heat-conducting manner. The die further has on its other side a linkage area, the cross-sectional area of which is at least in part of larger dimension than the recess in the circuit carrier and whose end is connected to a heat sink in a heat-conducting manner.

According to the invention a circuit carrier structure is thus provided, with which a reliable and improved heat transport from the SMD component to the heat sink is enabled. Advantageously, a chronologically independent development of the heat sink and component placement on the circuit carrier can take place, and at the same time the lowest possible thermal resistance realized. This can substantially reduce the development effort for a circuit carrier structure.

According to the invention, a printed circuit board (PCB) can advantageously be employed as the circuit carrier. The electronic components can be affixed to the circuit carrier using any familiar method, preferably by reflow soldering methods. The recess can, for example, be created in the circuit carrier by drilling or grinding, and its peripheral dimensions can in each case be made smaller than the corresponding dimensions of the SMD component, so that secure fastening of the SMD-component to the circuit carrier continues to be guaranteed. The recess can be metalized, preferably provided with a separate copper coating.

According to the invention the die has a joining area and a linkage area. The term joining area is taken according to the invention to mean that part of the die facing the circuit carrier, and whose end is introduced into the recess in the circuit carrier. The joining area of the die and the recess can advantageously be embodied as a fit. Therefore the circumferential form of the joining area can be adjusted to the recess, so that an advantageous press fit results. The coupling of heat into the circuit carrier in the connection area and also the mechanical fixing of the die can hereby be improved. The joining area can extend to the full thickness of the circuit carrier or protrude beyond it. According to the invention the linkage area is understood to mean that part of the die facing the heat sink and whose end area is connected to the heat sink in a heat-conducting manner. The linkage area of the die has at least in part a larger cross-sectional area than the recess in the circuit carrier. By the thus enlarged surface, heat can dissipate laterally more effectively to the environment and at its end more effectively to the heat sink. The die with its joining area and linkage area is preferably embodied as one-piece, as the lowest thermal resistance is thereby guaranteed. It can also, however, be constructed from a number of parts, which are in turn connected to each other in a heat-conducting manner.

In a preferred embodiment, the die can have a step to the joining area as a result of the enlarged cross section of the linkage area. Similarly preferably, the cross section of the die can continuously expand from the joining area to the linkage area, so that for example an essentially conical form results. Alternatively, the cross section of the die in the linkage area can once more taper towards its end area.

In another preferred embodiment the linkage area of the die can additionally have a screw thread for connection to the heat sink. The mechanical stability of the connection to the heat sink can thereby be significantly improved.

The heat-conducting cement can be based on any known base adhesive matrix, for example silicon, epoxide, polyurethane or polyimide. As a result of the proportion of metallic or ceramic fillers contained in the base matrix, heat-conducting cements can advantageously ensure good heat-conducting properties from the SMD component to the die. Moreover, according to the invention, sufficient heat-conducting cement can be used to create a closed connection between the circuit carrier and the die in the recess. This serves to improve not just the mechanical attachment, but also the coupling of the heat into the printed circuit board in this connection area.

The die can preferably be formed of a metallic or a ceramic material. It particularly preferably contains aluminum, which is capable of dissipating heat in an especially effective manner.

In a further preferable embodiment, the die can contain a solderable material, preferably CuNi, Nickel <Alloy 42>, Sn or Ag. Equally preferably, the die can be provided with a solderable coating, preferably AuNi, Sn, Ag, Pt or Pd.

In order to achieve improved and defined heat dissipation, in a preferred development the die can be linked to the heat sink via a thermal interface material, for example screwed, pressed, welded or glued. Thermal interface material is understood to mean material with which the thermal contact resistance as a result of surface roughness between the die and the heat sink can advantageously be reduced. Depending on requirements, the thermal interface material can be an electrical insulating or electrically conductive material. Examples of thermal interface materials are heat-conducting materials such as cements, pastes, gels or adhesive foils, like polyimide foils or ceramic-filled silicon foils.

In a further preferred embodiment, the die can at least in part be provided with longitudinal grooves. In this way the surface of the die can be enlarged, and the direct heat dissipation to the particular environment improved. Especially preferably, the die can have longitudinal grooves in the joining area, and additionally advantageously prevent relative movements between the circuit carrier and the die, and contribute to the mechanical attachment of the die to the circuit carrier.

In another preferred embodiment, the die can be provided with an electrically insulating coating. This coating can serve as an electrical overvoltage protection. In this way, electrical potential-driven components can also advantageously be connected to the heat sink with the thermally conductive die, and at the same time reliable heat transport is enabled. The electrically insulating coating can, for example, be a layer of varnish, an enamel layer, an anodized layer or an electrically insulating foil layer, for example made of polyimide or Teflon. In a particularly preferred embodiment, the die contains anodized aluminum. The coating can advantageously have a thickness in the range <−25 pm, so that good heat dissipation is still guaranteed.

To manufacture a circuit carrier structure according to the invention with at least one electronic component using SMD technology, a continuous recess is created in the circuit carrier underneath the component. The recess can for example be created by grinding or drilling and subsequently metalized if applicable. The SMD component can be attached to the circuit carrier in a known manner, for example by soft solder. A small amount of heat-conducting cement can be introduced into the recess, which can advantageously guarantee good heat dissipation as a result of the proportions of metallic or ceramic fillers contained therein. The end of the joining area of a die made of a heat-conducting material is subsequently introduced into the recess, and fixed to the SMD component and to the circuit carrier with the heat-conducting cement. The amount of heat-conducting cement material used here depends on the contact surface to the die, the filler used and the thickness of its coating. The coating thickness can ideally be selected based on the particle distribution of customary fillers.

The lower limit of the coating thickness is here oriented towards the largest filler particles. The usual materials have particles sizes of 40 pm. The mass of the filler is here determined according to the formula M=V·φ, where φ is the specific thickness of the filler material, which typically lies between 2 and 4 g/cm³ and V the volume V=A·d_{layer} (A=area d=thickness) of the gap to be filled. The die can then be connected to a heat sink with the end of its linkage area. The connection can, for example, be effected by screwing, pressing, welding or gluing.

In this way, circuit carrier structures with thermally loaded SMD components with high long-term stability can be provided.

Other features which are considered as characteristic for the invention are set forth in the appended claims.

Although the invention is illustrated and described herein as embodied in a circuit carrier structure with improved heat dissipation, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWING

The single FIGURE of the drawing is a diagrammatic, cross-sectional view of a circuit carrier structure according to the invention.

### DETAILED DESCRIPTION OF THE INVENTION

Referring now to the single FIGURE of the drawing in detail, there is shown a cross-sectional representation of a circuit carrier structure 1, with an SMD component 3a, 3b attached to a circuit carrier 2. The SMD component is embodied by a main body 3a and a heat vane as a lower part 3b, which advantageously contributes to mechanical support and heat dissipation. The SMD component 3 is preferably attached to the circuit carrier 2 by soft solder 4. The circuit carrier 2 is especially preferably a PCB (Printed Circuit Board). Underneath the SMD component 3, a recess 5 is built in to the circuit carrier, which can be, for example, drilled or ground. The recess 5 can be metalized, preferably provided with a separate copper coating. One end of a die 6a, 6b made of heat-conducting metallic or ceramic material is introduced into the recess 5, and attached to the heat vane 3b with a layer of heat-conducting cement 7. The die has a joining area 6a and a linkage area 6b. The end of the joining area 6a is the end of the die, which is introduced into the recess in the circuit carrier, while the linkage area 6b is connected to a heat sink 8 with its end. The linkage area 6b has at least in part a greater cross-sectional area than the recess 5 in the circuit carrier 2. The end of the linkage area 6b can preferably be connected with the heat sink 8 by a layer of thermal interface material 9, for example screwed, pressed, welded or glued. Thermal contact resistances arising as a result of surface roughness between the die 6a, 6b and the heat sink 8 can hereby be advantageously reduced. The die 6a, 6b can at least in part, preferably in the joining area 6a, be provided with longitudinal grooves 10. In this way, on the one hand, the surface of the die 6a, 6b can be enlarged and the direct heat dissipation to the atmosphere improved. On the other hand and additionally advantageously, relative movements between the circuit carrier 2 and the die 6a, 6b can be prevented.

To summarize, a circuit carrier concept is accordingly proposed, in which the heat dissipation and linkage of a SMD component to a heat sink can be improved, and reliably ensured with long-term stability. The circuit carrier provided can here be custom-made in a simple and variable manner, and can be manufactured using standard processes. Advantageously, the concept according to the invention enables the lowest possible thermal resistance to be realized, while the heat sink and component placement on the circuit carrier can nevertheless be developed independently of each other. Assembly can thus be easily and cost-effectively integrated into the overall assembly process of an electronic device.

1. A circuit carrier structure, comprising:
at least one electronic component formed using SMD technology;
a heat sink;
a circuit carrier disposed underneath said at least one electronic component and having a continuous recess formed therein;
a die made of a heat-conducting material and having a joining area with a first end disposed in said continuous recess, said die connected with said electronic component in a heat-conducting manner and further having a linkage area on a side opposite said joining area, said linkage area having a cross-sectional area being at least in part greater in dimension than said continuous recess in said circuit carrier, said linkage area having an end connected with said heat sink in a heat-conducting manner; and
a heat-conducting layer fixing said die in said recess.

2. The circuit carrier structure according to claim 1, wherein said die is formed of a material selected from the group consisting of a metallic material and a ceramic material.

3. The circuit carrier structure according to claim 1, wherein said die has a generally conical form.

4. The circuit carrier structure according to claim 1, wherein said linkage area of said die tapers in cross section towards an end area.

5. The circuit carrier structure according to claim 1, wherein said linkage area of said die has a screw thread for connecting with said heat sink.

6. The circuit carrier structure according to claim 1, wherein said die contains a solderable material.

7. The circuit carrier structure according to claim 1, wherein said die has a solderable coating.

8. The circuit carrier structure according to claim 1, wherein said die has an electrically insulating coating.

9. The circuit carrier structure according to claim 8, wherein said electrically insulating coating has one of an anodized layer, a layer of varnish, an enamel layer and an electrically insulating foil layer.

10. The circuit carrier structure according to claim 1, wherein said die has longitudinal grooves formed therein at least in part.

11. The circuit carrier structure according to claim 1, further comprising a thermal interface material disposed between said linkage area and said heat sink.

12. The circuit carrier structure according to claim 11, wherein said thermal interface material is one of an electrically insulating material and an electrically conductive material.

13. The circuit carrier structure according to claim 6, wherein said solderable material is selected from the group consisting of CuNi, Nickel <Alloy 42>, Sn and Ag.

14. The circuit carrier structure according to claim 10, wherein said longitudinal grooves are formed in said joining area.

15. A method for manufacturing a circuit carrier structure formed using SMD technology, which comprises the steps of:
providing a circuit carrier supporting an electronic component;
forming a continuous recess in the circuit carrier underneath the electronic component;
applying a heat-conducting cement layer to the continuous recess;
inserting one end of a joining area of a die made of one of a heat-conducting metallic material and a ceramic material in the continuous recess, and fixing the joining area in place with the heat-conducting cement layer; and
connecting the die to a heat sink with an end of a linkage area of the die, in a heat-conducting manner.

16. The method according to claim 15, which further comprises metalizing the continuous recess.

17. A method of using a circuit carrier structure according to claim 1, which comprises the steps of:
using the circuit carrier structure in an application in the automotive industry.
